(19) United States
(12) Patent Application Publication
(10) Pub. No.: US 2026/0344195 A1
(43) Pub. Date: Oct. 29, 2026

(54) DISPLAY PANEL AND DISPLAY DEVICE

(71) Applicants: Kunshan Govisionox Optoelectronics Co., Ltd., Kunshan (CN); Visionox Technology Inc., Kunshan (CN)

(72) Inventors: Ying SHEN, Kunshan (CN); Deqiang ZHANG, Kunshan (CN)

(73) Assignees: Kunshan Govisionox Optoelectronics Co., Ltd., Kunshan (CN); Visionox Technology Inc., Kunshan (CN)

(21) Appl. No.: 19/711,870

(22) Filed: Jun. 17, 2026

(30) Foreign Application Priority Data
Jul. 4, 2025 (CN) 202510926767.5

(51) Int. Cl. H10K 59/122; H10K 59/80

(52) U.S. Cl. CPC H10K 59/122; H10K 59/80515

(57) ABSTRACT

The present application provides a display panel and a display device. The display panel includes: a substrate; a pixel defining layer located on one side of the substrate, the pixel defining layer defining a plurality of pixel openings; a plurality of light-emitting devices, each light-emitting device including a light-emitting functional layer and a first electrode layer, the light-emitting functional layer and the first electrode layer being located in the pixel openings; and the first electrode layer is located on a side of the light-emitting functional layer away from the substrate, and a thickness of the first electrode layer is less than or equal to 10 nm; along a direction perpendicular to a plane where the substrate is located, the light-emitting functional layer includes at least two stacked light-emitting units, adjacent light-emitting units being connected in series.

### CROSS-REFERENCE TO RELATED APPLICATION

The present application claims priority to the Chinese Patent Application No. 202510926767.5, filed on Jul. 4, 2025, and the entire contents of the above application are hereby incorporated by reference in its entirety.

### FIELD

The present application relates to the field of display technology, specifically to a display panel and a display device.

### BACKGROUND

OLED (Organic Light-Emitting Diode) displays have advantages such as high contrast, rich and accurate colors, fast response speed, and wide viewing angle, and have received widespread attention. With the rapid development of OLED display technology, top-emitting OLED display panels have become a main choice for high-end display products due to their advantages such as wide color gamut, self-luminescence, and high aperture ratio, especially flexible OLED display panels which have been widely used. However, limited by the existing technology, current OLED display panels still cannot meet the requirements.

### SUMMARY

In view of this, embodiments of the present application provide a display panel and a display device.

An embodiment of the present application provides a display panel, including: a substrate, a pixel defining layer and a plurality of light-emitting devices. The pixel defining layer located on one side of the substrate, the pixel defining layer defining a plurality of pixel openings.

Each light-emitting device including a light-emitting functional layer and a first electrode layer, the light-emitting functional layer and the first electrode layer being located in the pixel opening.

In one embodiment, the first electrode layer is located on a side of the light-emitting functional layer away from the substrate, and a thickness of the first electrode layer is less than or equal to 10 nm; in a direction perpendicular to a plane where the substrate is located, the light-emitting functional layer includes at least two stacked light-emitting units, and adjacent light-emitting units are connected in series.

In one embodiment, the display panel further including: a partition structure, surrounding at least a portion of the pixel opening, for partitioning the light-emitting functional layer between adjacent light-emitting devices.

In one embodiment, a number of partition structures on a periphery of one pixel opening is at least one, and the partition structure including a first sub-partition structure and a second sub-partition structure, and the first sub-partition structure extending along a first direction, the second sub-partition structure extending along a second direction. In the first direction, opposite ends of the first sub-partition structure extend beyond the pixel opening. In the second direction, opposite ends of the second sub-partition structure extend beyond the pixel opening. The first direction intersecting the second direction.

In one embodiment, the partition structure further includes a third sub-partition structure and a fourth sub-partition structure, in the second direction, the first sub-partition structure and the third sub-partition structure being located on opposite sides of the pixel opening, in the first direction, the second sub-partition structure and the fourth sub-partition structure being located on opposite sides of the pixel opening; in the first direction, opposite ends of the third sub-partition structure extending beyond the pixel opening; in the second direction, opposite ends of the fourth sub-partition structure extending beyond the pixel opening.

In one embodiment, the first sub-partition structure, the second sub-partition structure, the third sub-partition structure, and the fourth sub-partition structure are connected end to end in sequence.

In one embodiment, at least one partition structure is provided between adjacent pixel openings.

In one embodiment, the partition structure includes a first groove, the first groove being located in the pixel defining layer, the first groove surrounding at least a portion of the pixel opening.

In one embodiment, a depth of the first groove is less than or equal to a thickness of the pixel defining layer.

In one embodiment, the depth of the first groove is greater than or equal to 1 μm and less than or equal to 2 μm.

In one embodiment, a width of the first groove is greater than or equal to 1 μm and less than or equal to 10 μm.

In one embodiment, a number of first grooves on a periphery of one pixel opening is at least one. The first groove includes a first sub-groove and a second sub-groove. The first sub-groove extending along a first direction. The second sub-groove extending along a second direction. In the first direction, opposite ends of the first sub-groove extending beyond the pixel opening. In the second direction, opposite ends of the second sub-groove extending beyond the pixel opening.

In one embodiment, the first groove further includes a third sub-groove and a fourth sub-groove. In the second direction, the first sub-groove and the third sub-groove being located on opposite sides of the pixel opening. In the first direction, the second sub-groove and the fourth sub-groove being located on opposite sides of the pixel opening. In the first direction, opposite ends of the third sub-groove extending beyond the pixel opening. In the second direction, opposite ends of the fourth sub-groove extending beyond the pixel opening.

In one embodiment, the first sub-groove, the second sub-groove, the third sub-groove, and the fourth sub-groove are connected end to end in sequence.

In one embodiment, at least one first groove is provided between adjacent pixel openings.

In one embodiment, it further includes: a first auxiliary conductive structure, located between the pixel defining layer and the substrate, at least a portion of the first auxiliary conductive structure being exposed in the first groove, the first auxiliary conductive structure being electrically connected to the first electrode layer.

In one embodiment, the light-emitting device includes a first light-emitting device and a second light-emitting device, the first auxiliary conductive structure includes a first sub-auxiliary conductive structure and a second sub-auxiliary conductive structure, the first sub-auxiliary conductive structure being electrically connected to the first electrode layer of the first light-emitting device, the second sub-auxiliary conductive structure being electrically connected to the first electrode layer of the second light-emitting device; the first sub-auxiliary conductive structure and the second sub-auxiliary conductive structure are spaced apart, or the first sub-auxiliary conductive structure and the second sub-auxiliary conductive structure are electrically connected.

In one embodiment, the first groove penetrates the pixel defining layer, at least a portion of the first sub-auxiliary conductive structure and at least a portion of the second sub-auxiliary conductive structure are located in the first groove.

In one embodiment, the light-emitting device further includes a second electrode layer, located between the pixel defining layer and the substrate, at least a portion of the second electrode layer being exposed in the pixel opening, the first auxiliary conductive structure being disposed in the same layer as the second electrode layer.

In one embodiment, in a first direction, a width of an orthographic projection of the first auxiliary conductive structure on the substrate is greater than or equal to 3 μm and less than or equal to 6 μm; in a second direction, a width of an orthographic projection of the first auxiliary conductive structure on the substrate is greater than or equal to 3 μm and less than or equal to 6 μm, the first direction intersecting the second direction.

In one embodiment, the display panel further includes a second auxiliary conductive structure, located on a side of the second electrode layer away from the pixel defining layer, the first auxiliary conductive structure being electrically connected to the second auxiliary conductive structure.

In one embodiment, the substrate includes a planarization layer, the planarization layer having a first via hole; the second auxiliary conductive structure is located on a side of the planarization layer away from the second electrode layer, the first auxiliary conductive structure being electrically connected to the second auxiliary conductive structure through the first via hole.

In one embodiment, the display panel further includes: a fourth auxiliary conductive structure, located on a side of the first electrode layer away from and/or close to the substrate, the fourth auxiliary conductive structure being transparent.

In one embodiment, the fourth auxiliary conductive structure includes a first metal element, the first auxiliary conductive structure includes a second metal element, the first metal element being the same as the second metal element.

In one embodiment, the fourth auxiliary conductive structure includes a first metal element, the second auxiliary conductive structure includes a third metal element, the first metal element being the same as the third metal element.

In one embodiment, the substrate includes a base substrate and a planarization layer, the planarization layer being located on a side of the base substrate close to the pixel defining layer. The partition structure further includes a second groove located in the planarization layer. The second groove communicating with the first groove, and an orthographic projection of the second groove on the base substrate is within a range of an orthographic projection of the first groove on the base substrate.

In one embodiment, a width of the second groove gradually decreases along a direction away from the base substrate; or, a sidewall of the second groove is perpendicular to the base substrate.

In one embodiment, a depth of the second groove is less than or equal to a thickness of the planarization layer.

In one embodiment, the partition structure further includes: a partition portion, the partition portion being located on a side of the second groove close to the first groove, an orthographic projection of the partition portion on the base substrate overlapping with an orthographic projection of an opening of the second groove on the base substrate.

In one embodiment, a material of the partition portion includes at least one of a conductive material and an insulating material.

In one embodiment, the light-emitting device further includes a second electrode layer, located between the pixel defining layer and the substrate, at least a portion of the second electrode layer being exposed in the pixel opening. The partition portion is located between the planarization layer and the second electrode layer, or the partition portion is disposed in the same layer as the second electrode layer and spaced apart from the second electrode layer.

In one embodiment, the partition portion extends along a circumferential direction of the second groove. In one embodiment, it further includes: a third auxiliary conductive structure, located in the first groove and on a side of the partition portion away from the base substrate, the third auxiliary conductive structure being electrically connected to the first electrode layer.

In one embodiment, the light-emitting device includes a first light-emitting device and a second light-emitting device. The third auxiliary conductive structure includes a third sub-auxiliary conductive structure and a fourth sub-auxiliary conductive structure. The third sub-auxiliary conductive structure being electrically connected to the first electrode layer of the first light-emitting device. The fourth sub-auxiliary conductive structure being electrically connected to the first electrode layer of the second light-emitting device. The third sub-auxiliary conductive structure and the fourth sub-auxiliary conductive structure are spaced apart, or the third sub-auxiliary conductive structure and the fourth sub-auxiliary conductive structure are electrically connected.

In one embodiment, the third auxiliary conductive structure is disposed in the same layer as the second electrode layer.

In one embodiment, in a first direction, a width of an orthographic projection of the third auxiliary conductive structure on the substrate is greater than or equal to 3 μm and less than or equal to 6 μm;. In a second direction, a width of an orthographic projection of the third auxiliary conductive structure on the substrate is greater than or equal to 3 μm and less than or equal to 6 μm, the first direction intersecting the second direction.

In one embodiment, the display panel further includes a second auxiliary conductive structure, located on a side of the partition portion away from the pixel defining layer, the partition portion having a second via hole, the third auxiliary conductive structure being electrically connected to the second auxiliary conductive structure through the second via hole.

In one embodiment, the substrate includes a planarization layer, the planarization layer having a first via hole; the display panel further includes a second auxiliary conductive structure, the second auxiliary conductive structure being located on a side of the planarization layer away from the second electrode layer, the third auxiliary conductive structure being electrically connected to the second auxiliary conductive structure through the first via hole.

In one embodiment, the display panel further includes: a fourth auxiliary conductive structure, located on a side of the first electrode layer away from and/or close to the substrate, the fourth auxiliary conductive structure being transparent.

In one embodiment, the fourth auxiliary conductive structure includes a first metal element, the third auxiliary conductive structure includes a fourth metal element, the first metal element being the same as the fourth metal element.

In one embodiment, the partition structure includes an isolation structure, the isolation structure includes a first surface and a second surface disposed opposite to each other, the first surface is located on a side of the second surface away from a pixel defining layer, and an orthographic projection of the second surface on a substrate is within an orthographic projection range of the first surface on the substrate; the isolation structure is electrically connected to a first electrode layer.

In one embodiment, the isolation structure includes a first isolation portion and a second isolation portion, the first isolation portion is located on a side of the second isolation portion away from the pixel defining layer, and an orthographic projection of the second isolation portion on the substrate is within an orthographic projection range of the first isolation portion on the substrate; the second isolation portion is electrically connected to the first electrode layer.

In one embodiment, the isolation structure further includes a third isolation portion located on a side of the second isolation portion close to the pixel defining layer, and an orthographic projection of the second isolation portion on the substrate is within an orthographic projection range of the third isolation portion on the substrate; the third isolation portion is electrically connected to the first electrode layer.

In one embodiment, the partition structure further includes a first groove, the first groove is located in the pixel defining layer, and the first groove surrounds at least a portion of a pixel opening; the isolation structure surrounds at least a portion of the first groove.

In one embodiment, a depth of the first groove is less than or equal to a thickness of the pixel defining layer. In one embodiment, the depth of the first groove is greater than or equal to 1 μm and less than or equal to 2 μm. In one embodiment, a width of the first groove is greater than or equal to 1 μm and less than or equal to 10 μm. In one embodiment, a number of first grooves on a peripheral side of one pixel opening is at least one, the first groove includes a first sub-groove and a second sub-groove, the first sub-groove extends along a first direction, and the second sub-groove extends along a second direction; in the first direction, opposite ends of the first sub-groove extend beyond the pixel opening, and in the second direction, opposite ends of the second sub-groove extend beyond the pixel opening.

In one embodiment, the first groove further includes a third sub-groove and a fourth sub-groove, in the second direction, the first sub-groove and the third sub-groove are located on opposite sides of the pixel opening, and in the first direction, the second sub-groove and the fourth sub-groove are located on opposite sides of the pixel opening; in the first direction, opposite ends of the third sub-groove extend beyond the pixel opening; in the second direction, opposite ends of the fourth sub-groove extend beyond the pixel opening.

In one embodiment, the first sub-groove, the second sub-groove, the third sub-groove, and the fourth sub-groove are sequentially connected end to end.

In one embodiment, at least one first groove is provided between adjacent pixel openings. In one embodiment, the isolation structure encloses a plurality of isolation openings, an orthographic projection of the pixel opening on the substrate falls within an orthographic projection range of the isolation opening on the substrate.

In one embodiment, the isolation structure has a first opening. An orthographic projection of the first groove on the substrate is within an orthographic projection range of the first opening on the substrate. A shape of an orthographic projection of the isolation structure on the substrate includes a mesh shape. In one embodiment, the light-emitting device further includes a second electrode layer located between the pixel defining layer and the substrate, and at least a portion of the second electrode layer is exposed in the pixel opening. Along an extension direction of the first groove, a length of the isolation structure is less than a length of the first groove. The display panel further includes a second auxiliary conductive structure located on a side of the second electrode layer away from the pixel defining layer, and the isolation structure is electrically connected to the second auxiliary conductive structure.

In one embodiment, the substrate includes a planarization layer, and the planarization layer has a first via hole; the second auxiliary conductive structure is located on a side of the planarization layer away from the second electrode layer, and the isolation structure is electrically connected to the second auxiliary conductive structure through the first via hole. In one embodiment, the substrate includes a base substrate and a planarization layer, the planarization layer is located on a side of the base substrate close to the pixel defining layer. The partition structure further includes a second groove located in the planarization layer. The second groove communicates with the first groove, and an orthographic projection of the first groove on the base substrate is within an orthographic projection range of the second groove on the base substrate.

In one embodiment, along a direction away from the base substrate, a width of the second groove gradually decreases; or, a sidewall of the second groove is perpendicular to the base substrate.

In one embodiment, the partition structure further includes a partition portion located on a side of the second groove close to the first groove, and an orthographic projection of the partition portion on the base substrate overlaps with an orthographic projection of an opening of the second groove on the base substrate.

In one embodiment, a material of the partition portion includes an insulating material. In one embodiment, the light-emitting device further includes a second electrode layer located between the pixel defining layer and the substrate, and at least a portion of the second electrode layer is exposed in the pixel opening.The partition portion is located between the planarization layer and the second electrode layer.

In one embodiment, the partition portion extends along a circumferential direction of the second groove. In one embodiment, the display panel further includes a second auxiliary conductive structure located on a side of the partition portion away from the pixel defining layer. The partition portion has a second via hole, and the isolation structure is electrically connected to the second auxiliary conductive structure through the second via hole.

In one embodiment, a thickness of the first electrode layer is less than or equal to 5 nm. In one embodiment, a material of the first electrode layer includes a metal. In one embodiment, the metal includes at least one of magnesium, silver, aluminum, tin, gallium, and zinc.

In one embodiment, the display panel further includes a fourth auxiliary conductive structure located on a side of the first electrode layer away from and/or close to the substrate.The fourth auxiliary conductive structure being transparent.

In one embodiment, a material of the fourth auxiliary conductive structure includes at least one of indium tin oxide, aluminum-doped zinc oxide, gallium-doped zinc oxide, fluorine-doped zinc oxide, indium zinc oxide, and indium gallium zinc oxide.

An embodiment of the present application provides a display device, including the above display panel. According to the display panel provided in the embodiments of the present application, the thickness of the first electrode layer is relatively thin, which is beneficial for improving the light transmittance of the first electrode layer, and can also weaken the microcavity effect of the light-emitting device, allowing light at larger angles to be emitted, thereby improving the large viewing angle color shift problem of the display panel. At the same time, the light-emitting device including light-emitting units arranged in series is beneficial for reducing the power consumption of the display panel, thereby improving the performance of the display panel.

### BRIEF DESCRIPTION OF THE DRAWINGS

FIG. 1 is a schematic cross-sectional structural view of a display panel in the related art.

FIG. 2 is a schematic cross-sectional structural view of a display panel in one embodiment of the present application.

FIG. 3 is an enlarged partial structural view of the light-emitting device at A in FIG. 2.

FIG. 4 is a schematic cross-sectional structural view of a display panel in another embodiment of the present application.

FIG. 5 is a schematic top structural view of a display panel in one embodiment of the present application.

FIG. 6 is a schematic top structural view of a display panel in another embodiment of the present application.

FIG. 7 is a schematic top structural view of a display panel in another embodiment of the present application.

FIG. 8 is a schematic top-view structural diagram of a display panel according to another embodiment of the present application.

FIG. 9 is a schematic cross-sectional structural diagram of a display panel according to another embodiment of the present application.

FIG. 10 is a schematic top-view structural diagram of a display panel according to another embodiment of the present application.

FIG. 11 is a schematic cross-sectional structural diagram of a display panel according to another embodiment of the present application.

FIG. 12 is a schematic cross-sectional structural diagram of a display panel according to another embodiment of the present application.

FIG. 13 is a schematic cross-sectional structural diagram of a display panel according to another embodiment of the present application.

FIG. 14 is a schematic cross-sectional structural diagram of a display panel according to another embodiment of the present application.

FIG. 15 is a schematic cross-sectional structural diagram of a display panel according to another embodiment of the present application.

FIG. 16 is a schematic cross-sectional structural diagram of a display panel according to another embodiment of the present application.

FIG. 17 is a schematic cross-sectional structural diagram of a display panel according to another embodiment of the present application.

FIG. 18 is a schematic cross-sectional structural diagram of a display panel according to another embodiment of the present application.

FIG. 19 is a schematic cross-sectional structural diagram of a display panel according to another embodiment of the present application.

FIG. 20 is a schematic cross-sectional structural diagram of a display panel according to another embodiment of the present application.

FIG. 21 is a schematic top-view structural diagram of a display panel according to another embodiment of the present application.

FIG. 22 is a schematic top-view structural diagram of a display panel according to another embodiment of the present application.

FIG. 23 is a schematic cross-sectional structural diagram of a display panel according to another embodiment of the present application.

FIG. 24 is a schematic top-view structural diagram of a display panel according to another embodiment of the present application.

### DETAILED DESCRIPTION

The embodiments of the present application will be clearly and completely described below with reference to the accompanying drawings in the embodiments of the present application. In one embodiment, the described embodiments are only a part of the embodiments of the present application, not all of the embodiments.

In addition, to better illustrate the present application, numerous specific details are given in the following detailed description. It should be understood that the present application can also be implemented without some specific details. In some instances, methods and means well known in the art are not described in detail to highlight the gist of the present application.

Similar reference numerals and letters denote similar items in the following drawings, so once an item is defined in one drawing, it does not need to be further defined and explained in subsequent drawings.

Furthermore, if the terms "first", "second", etc. appear, they are only used for distinguishing descriptions and should not be construed as indicating or implying relative importance.

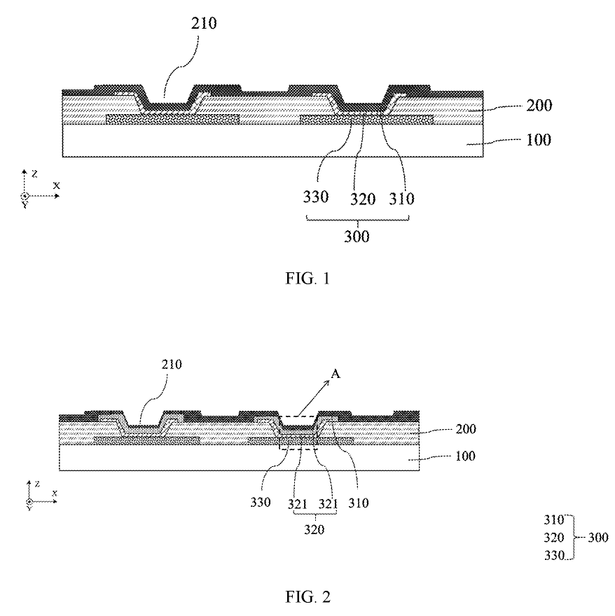

The inventors have found that reducing the thickness of the first electrode layer 310 in the light-emitting device 300 can alleviate the large viewing angle color shift problem. As shown in FIG. 1, this reduction improves light transmittance and reduces reflectivity, thereby decreasing both the number and intensity of reflections in the microcavity, weakening the microcavity effect. Furthermore, when the first electrode layer 310 is thin, the distance between the light-emitting functional layer 320 and the second electrode layer 330 changes, altering the optical path and further weakening the microcavity effect. Consequently, light with a wider wavelength range, such as light at large viewing angles, can be emitted, alleviating color shift. However, reducing the thickness of the first electrode layer 310 increases power consumption, which degrades display performance and user experience.

In view of this, an embodiment of the present application provides a display panel. As shown in the schematic cross-sectional structural diagram of a display panel shown in FIG. 2, the display panel includes: a substrate 100, a pixel defining layer 200, and a plurality of light-emitting devices 300.

In one embodiment, the pixel defining layer 200 is located on one side of the substrate 100, and the pixel defining layer 200 defines a plurality of pixel openings 210.

Exemplarily, the pixel defining layer 200 is formed using an inorganic insulating material of at least one of silicon nitride (SiNx), silicon oxide (SiOx), and silicon oxynitride (SiON).

In one embodiment, the light-emitting device 300 includes a light-emitting functional layer 320 and a first electrode layer 310, and the light-emitting functional layer 320 and the first electrode layer 310 are located in the pixel opening 210. The first electrode layer 310 is located on a side of the light-emitting functional layer 320 away from the substrate 100, and the thickness of the first electrode layer 310 is less than or equal to 10 nm (for example, it can be 1 nm, 2 nm, 3 nm, 4 nm, 5 nm, 6 nm, 7 nm, 8 nm, 9 nm, or 10 nm, etc.). Along a direction perpendicular to the plane where the substrate 100 is located, the light-emitting functional layer 320 includes at least two stacked light-emitting units 321, and adjacent light-emitting units 321 are connected in series.

According to the display panel provided by the embodiments of the present application, the thickness of the first electrode layer 310 is relatively thin, which is beneficial to improving the light transmittance of the first electrode layer 310, and can also weaken the microcavity effect of the light-emitting device 300, and light at a large angle can be emitted, alleviating the problem of large viewing angle color shift of the display panel. At the same time, the light-emitting device 300 includes the light-emitting units 321 arranged in series, which is beneficial to reducing the power consumption of the display panel, thereby improving the performance of the display panel.

In the same light-emitting device 300, the colors of adjacent light-emitting units 321 can be the same or different.

In one embodiment, the thickness of the first electrode layer 310 is less than or equal to 5 nm.

In one embodiment, the material of the first electrode layer 310 includes metal. For example, the metal includes at least one of magnesium, silver, aluminum, tin, gallium, and zinc. Thus, the conductive effect of the first electrode layer 310 is better.

In one embodiment, the light-emitting device 300 further includes a second electrode layer 330 located between the pixel defining layer 200 and the substrate 100, and the second electrode layer 330 is at least partially exposed in the pixel opening 210.

In one embodiment, one of the first electrode layer 310 and the second electrode layer 330 is an anode, and the other of the first electrode layer 310 and the second electrode layer 330 is a cathode. In a specific example, the first electrode layer 310 is a cathode, and the second electrode layer 330 is an anode.

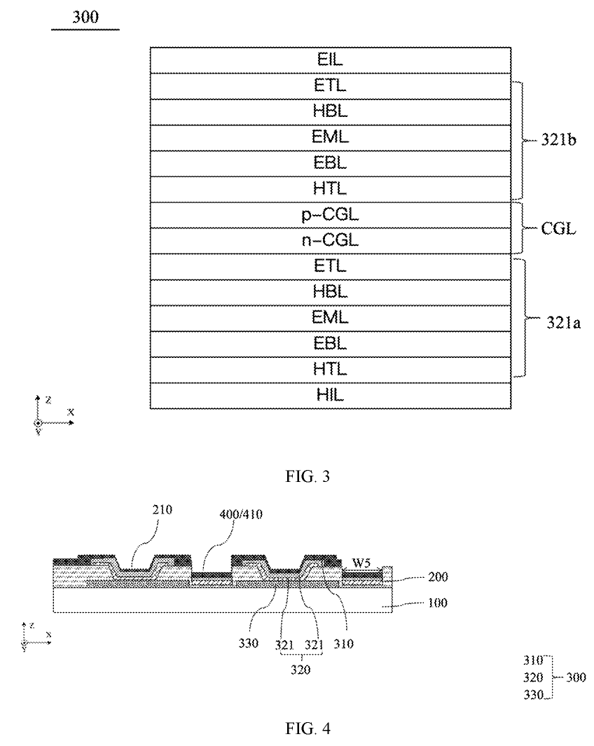

For example, as shown in the schematic cross-sectional structure diagram of the light-emitting device shown in FIG. 3, the light-emitting functional layer 320 further includes a charge generation layer CGL located between adjacent light-emitting units 321 to achieve a series connection of the adjacent light-emitting units 321.Through its own material properties and structural design, the charge generation layer CGL enables electrons and holes to be separated within it. The separated charges are injected into the adjacent light-emitting units 321 respectively. This achieves series operation of the multiple light-emitting units 321, allowing the entire series light-emitting device to emit light normally and exert its performance advantages.

For example, in the series light-emitting device, the charge generation layer CGL generally includes an n-CGL (electron-type charge generation layer) and a p-CGL (hole-type charge generation layer). The n-CGL is responsible for electron generation and transport, and the p-CGL is responsible for hole generation and transport. For example, the n-CGL provides electrons to an adjacent electron transport layer (ETL) of the next light-emitting unit, and prevents holes from the p-CGL from entering the n-CGL, avoiding energy loss caused by charge recombination. Materials for the n-CGL include but are not limited to zinc oxide (ZnO), titanium oxide (TiO2), BPhen (bathophenanthroline) doped with alkali metals (such as Li, Cs), combinations of C60 with metals (such as LiF/Ca), and the like. For example, the p-CGL provides holes to an adjacent hole transport layer (HTL) of the previous light-emitting unit, and prevents electrons from the n-CGL from entering the p-CGL, ensuring charge separation efficiency. Materials for the p-CGL include but are not limited to MoO₃, V₂O₅, WO₃, PEDOT:PSS, TAPC (4,4'-cyclohexylidenebis[N,N-bis(4-methylphenyl)aniline]), F4-TCNQ (2,3,5,6-tetrafluoro-7,7,8,8-tetracyanoquinodimethane), and the like.

Exemplarily, the at least two light-emitting units 321 include a first light-emitting unit 321a and a second light-emitting unit 321b. The first light-emitting unit 321a is located on a side of the second light-emitting unit 321b close to the substrate 100. Along a direction away from the substrate 100 (i.e., the Z direction), the first light-emitting unit 321a includes a hole transport layer HTL, an electron blocking layer EBL, a light-emitting material layer EML, a hole blocking layer HBL, and an electron transport layer ETL stacked in sequence. Similarly, along the direction away from the substrate 100, the second light-emitting unit 321b includes a hole transport layer HTL, an electron blocking layer EBL, a light-emitting material layer EML, a hole blocking layer HBL, and an electron transport layer ETL stacked in sequence. The n-CGL and the p-CGL are located between the first light-emitting unit 321a and the second light-emitting unit 321b, and the n-CGL is located on a side of the p-CGL close to the first light-emitting unit 321a.

Exemplarily, the light-emitting functional layer 320 further includes a hole injection layer (HIL) and an electron injection layer (EIL). The hole injection layer HIL is located between the second electrode layer 330 and the light-emitting functional layer 320, and the electron injection layer EIL is located between the first electrode layer 310 and the light-emitting functional layer 320. For example, the hole injection layer (HIL), the hole transport layer (HTL), the electron transport layer (ETL), the electron injection layer (EIL), and the charge generation layer (CGL) in the light-emitting functional layer 320 are all common film layers for multiple light-emitting devices, and thus can be referred to as common layers.

In one embodiment, referring to the schematic cross-sectional structure diagram of the display panel shown in FIG. 4. The display panel further includes a partition structure 400 that surrounds at least a portion of the pixel opening 210 and is used for partitioning the light-emitting functional layer 320 between adjacent light-emitting devices 300. Partitioning the light-emitting functional layer 320 between adjacent light-emitting devices 300 can separate the above common layers, which is beneficial for reducing the probability of crosstalk between adjacent light-emitting devices 300.

In one embodiment, the number of partition structures 400 on the periphery of one pixel opening 210 is at least one. The partition structure 400 includes a first sub-partition structure and a second sub-partition structure. The first sub-partition structure extends along a first direction X, and the second sub-partition structure extends along a second direction Y. In the first direction X, opposite ends of the first sub-partition structure extend beyond the pixel opening 210. In the second direction Y, opposite ends of the second sub-partition structure extend beyond the pixel opening 210. The first direction X intersects the second direction Y. The opposite ends of the first sub-partition structure extending beyond the pixel opening 210 and the opposite ends of the second sub-partition structure extending beyond the pixel opening 210 are beneficial for improving the effect of the partition structure 400 in partitioning the light-emitting functional layer 320 between adjacent light-emitting devices 300, and reducing the probability of crosstalk between adjacent light-emitting devices 300. In one embodiment, the partition structure 400 further includes a third sub-partition structure and a fourth sub-partition structure, in the second direction Y, the first sub-partition structure and the third sub-partition structure are located on opposite sides of the pixel opening 210, in the first direction X, the second sub-partition structure and the fourth sub-partition structure are located on opposite sides of the pixel opening 210; in the first direction X, opposite ends of the third sub-partition structure extend beyond the pixel opening 210; in the second direction Y, opposite ends of the fourth sub-partition structure extend beyond the pixel opening 210. This further improves the effect of the partition structure 400 in partitioning the light-emitting functional layer 320 between adjacent light-emitting devices 300 and reduces the probability of crosstalk between adjacent light-emitting devices 300.

In one embodiment, the first sub-partition structure, the second sub-partition structure, the third sub-partition structure, and the fourth sub-partition structure are sequentially connected end to end. Thus, the first sub-partition structure, the second sub-partition structure, the third sub-partition structure, and the fourth sub-partition structure form a closed structure, which improves the partitioning effect of the partition structure 400 on the light-emitting functional layer 320 between adjacent light-emitting devices 300 and reduces the probability of crosstalk.

In one embodiment, at least one partition structure is disposed between adjacent pixel openings 210.

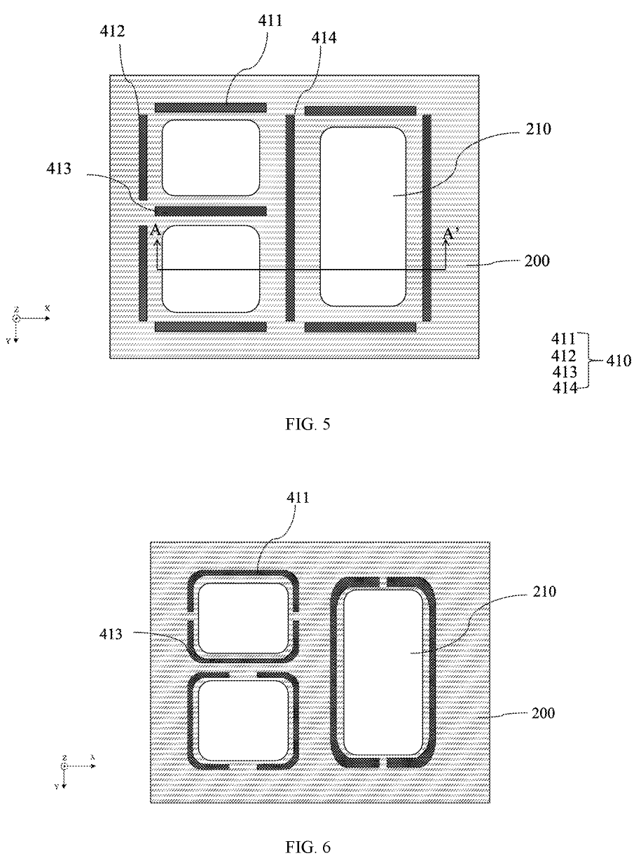

In one embodiment, referring to FIG. 4 and the schematic top view of the display panel shown in FIG. 5, the partition structure 400 includes a first groove 410, the first groove 410 is located in the pixel defining layer 200, and the first groove 410 surrounds at least a portion of the pixel opening 210. Thus, the light-emitting functional layer 320 is partitioned at the first groove 410, which is conducive to reducing the probability of crosstalk between adjacent light-emitting devices 300. FIG. 4 may be a schematic cross-sectional structural view of the display panel in FIG. 5 along the AA' direction. In one embodiment, the number of first grooves 410 on the periphery of one pixel opening 210 is at least one.

Exemplarily, the number of first grooves 410 on the periphery of one pixel opening 210 is multiple. The multiple first grooves 410 are discontinuous. The multiple first grooves 410 include a first sub-groove 411 and a second sub-groove 412. The first sub-groove 411 extends along a first direction X, and the second sub-groove 412 extends along a second direction Y. In the first direction X, opposite ends of the first sub-groove 411 extend beyond the pixel opening 210, and in the second direction Y, opposite ends of the second sub-groove 412 extend beyond the pixel opening 210.

For example, the first direction X is perpendicular to the second direction Y. "opposite ends of the first sub-groove 411 extend beyond the pixel opening 210" means that, in the first direction X, the first sub-groove 411 has opposite first and second ends, the pixel opening 210 has opposite third and fourth ends, the first end is adjacent to the third end, the second end is adjacent to the fourth end, the first end is located on a side of the third end away from the fourth end, and the second end is located on a side of the fourth end away from the third end. The meaning of "opposite ends of the second sub-groove 412 extend beyond the pixel opening 210" can be understood with reference to the above explanation.

For example, in the first direction X, one first groove 410 is provided on each of opposite sides of the pixel opening 210, and in the second direction Y, one first groove 410 is provided on each of opposite sides of the pixel opening 210, which can effectively partition the light-emitting functional layer 320, conducive to reducing the probability of crosstalk between adjacent light-emitting devices 300.

In one embodiment, the first groove 410 further includes a third sub-groove 413 and a fourth sub-groove 414, in the second direction Y, the first sub-groove 411 and the third sub-groove 413 are located on opposite sides of the pixel opening 210, in the first direction X, the second sub-groove 412 and the fourth sub-groove 414 are located on opposite sides of the pixel opening 210; in the first direction X, opposite ends of the third sub-groove 413 extend beyond the pixel opening 210; in the second direction Y, opposite ends of the fourth sub-groove 414 extend beyond the pixel opening 210. The meanings of "opposite ends of the third sub-groove 413 extend beyond the pixel opening 210" and "opposite ends of the fourth sub-groove 414 extend beyond the pixel opening 210" can be understood with reference to the above explanation, and will not be further elaborated here.

For example, referring to the schematic top view of the display panel shown in FIG. 6, the number of first grooves 410 on the periphery of one pixel opening 210 is two. The two first grooves 410 are oppositely disposed in the first direction X. The orthographic projection of each first groove 410 on the substrate 100 is in a "C" shape. The length of the pixel opening 210 surrounded by each first groove 410 accounts for 30% to 50% of the perimeter of the pixel opening 210. The two first grooves are spaced apart.

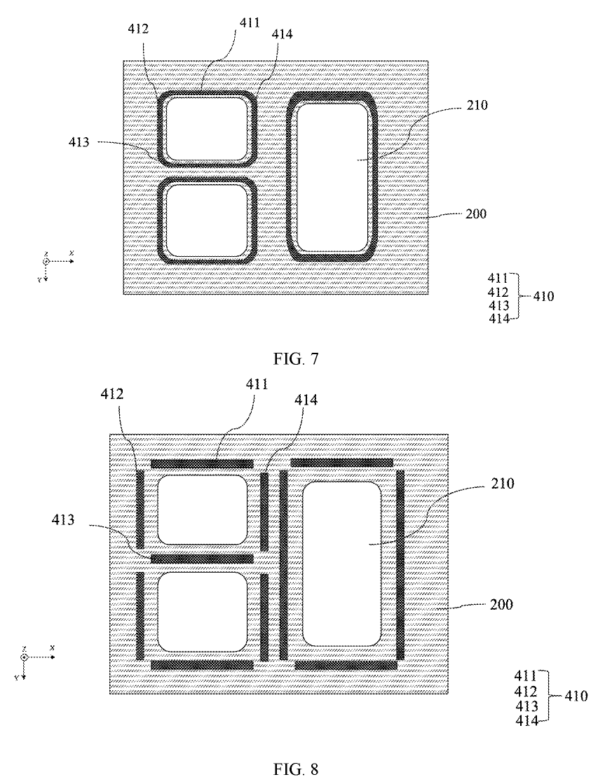

In some embodiments, the first sub-groove 411, the second sub-groove 412, the third sub-groove 413, and the fourth sub-groove 414 are sequentially connected end to end. Thus, the first sub-groove 411, the second sub-groove 412, the third sub-groove 413, and the fourth sub-groove 414 form a closed structure, constituting an annular through groove, which is more conducive to improving the effect of the partition structure 400 in partitioning the light-emitting functional layer 320 between adjacent light-emitting devices 300, and more conducive to reducing the probability of crosstalk between adjacent light-emitting devices 300. For example, referring to the schematic top view of the display panel shown in FIG. 7, one first groove 410 surrounds the periphery of the pixel opening 210. Thus, the effect of partitioning the light-emitting functional layer 320 is better, conducive to reducing the probability of crosstalk between adjacent light-emitting devices 300.

In some embodiments, referring to the schematic top view of the display panel shown in FIG. 8, there is at least one first groove 410 between adjacent pixel openings 210. Thus, the effect of partitioning the light-emitting functional layer 320 is better, conducive to reducing the probability of crosstalk between adjacent light-emitting devices 300. In some embodiments, the depth of the first groove 410 is less than or equal to the thickness of the pixel defining layer 200. The first groove 410 may or may not penetrate through the pixel defining layer 200. In one embodiment, the depth of the first groove 410 is greater than or equal to 1 μm and less than or equal to 2 μm, for example, it can be 1 μm, 1.2 μm, 1.4 μm, 1.6 μm, 1.8 μm, 2 μm, etc. In one embodiment, the width W5 of the first groove 410 is greater than or equal to 1 μm and less than or equal to 10 μm, for example, it can be 1 μm, 2 μm, 4 μm, 6 μm, 8 μm, 10 μm, etc.

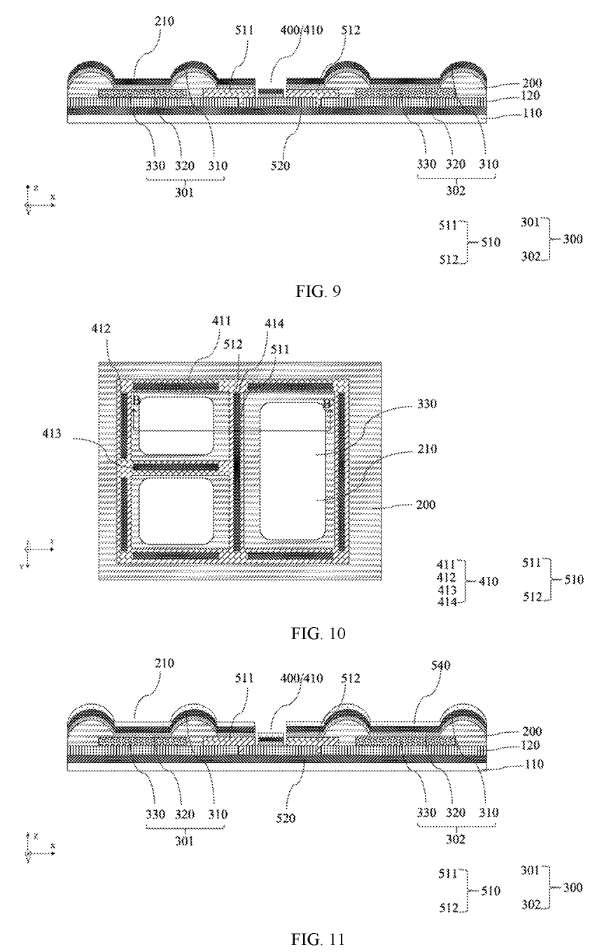

In one embodiment, referring to the cross-sectional structural schematic diagram of the display panel described in FIG. 9, the display panel further includes: a first auxiliary conductive structure 510, located between the pixel defining layer 200 and the substrate 100, at least a portion of the first auxiliary conductive structure 510 is exposed in the first groove 410, and the first auxiliary conductive structure 510 is electrically connected to the first electrode layer 310. Thus, it facilitates the transmission of signals in the first electrode layer 310, reducing the power consumption of the display panel. In this embodiment, a common layer (e.g., HTL, HIL, ETL, EIL, etc.) of the light-emitting functional layer 320 may also be included between the first auxiliary conductive structure 510 and the first electrode layer 310, and the first auxiliary conductive structure 510 is electrically connected to the first electrode layer 310 through the above common layer. In one embodiment, the light-emitting device 300 includes a first light-emitting device 301 and a second light-emitting device 302, the first auxiliary conductive structure 510 includes a first sub-auxiliary conductive structure 511 and a second sub-auxiliary conductive structure 512. The first sub-auxiliary conductive structure 511 is electrically connected to the first electrode layer 310 of the first light-emitting device 301. The second sub-auxiliary conductive structure 512 is electrically connected to the first electrode layer 310 of the second light-emitting device 302.

Exemplarily, in the first direction x, the width of the orthographic projection of the first auxiliary conductive structure 510 on the substrate 100 is greater than or equal to 3 μm and less than or equal to 6 μm (e.g., can be 3 μm, 4 μm, 5 μm, or 6 μm, etc.). In the second direction y, the width of the orthographic projection of the first auxiliary conductive structure 510 on the substrate 100 is greater than or equal to 3 μm and less than or equal to 6 μm (e.g., can be 3 μm, 4 μm, 5 μm, or 6 μm, etc.), and the first direction x intersects the second direction y.

Exemplarily, the first sub-auxiliary conductive structure 511 and the second sub-auxiliary conductive structure 512 are spaced apart from each other. In one embodiment, the display panel further includes a second auxiliary conductive structure 520, located on a side of the second electrode layer 330 away from the pixel defining layer 200, and the first auxiliary conductive structure 510 is electrically connected to the second auxiliary conductive structure 520. Exemplarily, the substrate 100 includes a planarization layer 120. The planarization layer 120 having a first via hole. The second auxiliary conductive structure 520 is located on a side of the planarization layer 120 away from the second electrode layer 330, and the first sub-auxiliary conductive structure 511 and the second sub-auxiliary conductive structure 512 are respectively electrically connected to the second auxiliary conductive structure 520 through the first via hole. Thus, it facilitates achieving a full-surface cathode.

Exemplarily, referring to FIG. 10, and FIG. 10 only shows main structures such as the first electrode layer, the pixel defining layer, and the first auxiliary conductive structure, and should not be construed as limiting the present application. The first sub-auxiliary conductive structure 511 is electrically connected to the second sub-auxiliary conductive structure 512. For example, on a side of the pixel defining layer 200 where the first groove 410 is not provided, away from the substrate 100, the first sub-auxiliary conductive structure 511 is electrically connected to the second sub-auxiliary conductive structure 512. FIGS. 9, 11 - 16 are cross-sectional structural schematic diagrams of the display panel in FIG. 10 along the BB' direction.

Exemplarily, the first auxiliary conductive structure 510 is disposed in the same layer as the second electrode layer 330. The first groove 410 penetrates the pixel defining layer 200, and at least a portion of the first sub-auxiliary conductive structure 511 and at least a portion of the second sub-auxiliary conductive structure 512 are located in the first groove 410.

For example, along a direction away from the substrate 100, the second electrode layer 330 includes stacked indium tin oxide, silver, and indium tin oxide, and the first auxiliary conductive structure 510 also includes stacked indium tin oxide, silver, and indium tin oxide. The silver in the middle layer of the first auxiliary conductive structure 510 located in the first groove 410 is eluted. Thus, the first auxiliary conductive structure 510 can serve as part of a partition structure for partitioning the light-emitting functional layer 320.

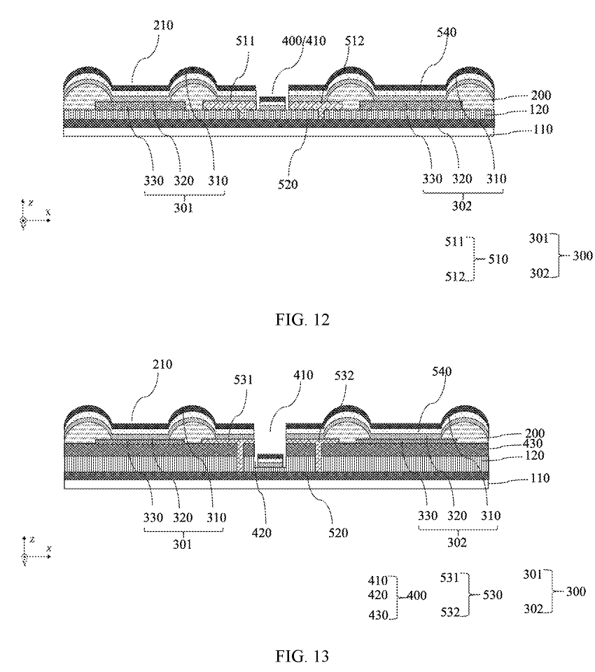

In one embodiment, as shown in FIGS. 11 and 12, the display panel further includes a fourth auxiliary conductive structure 540. The fourth auxiliary conductive structure located on a side of the first electrode layer 310 away from (refer to FIG. 11) and/or close to (refer to FIG. 12) the substrate 100, and the fourth auxiliary conductive structure 540 is transparently arranged. This facilitates reducing the impedance of the first electrode layer 310, reducing the power consumption of the display panel. In one embodiment, the fourth auxiliary conductive structure 540 includes a first metal element, the first auxiliary conductive structure 510 includes a second metal element, and the first metal element is the same as the second metal element. This helps make the conductivities of the first auxiliary conductive structure 510 and the fourth auxiliary conductive structure 540 similar, resulting in more stable conductive effects and alleviating uneven display images. In one embodiment, the fourth auxiliary conductive structure 540 includes a first metal element, the second auxiliary conductive structure 520 includes a third metal element, and the first metal element is the same as the third metal element. This helps make the conductivities of the second auxiliary conductive structure 520 and the fourth auxiliary conductive structure 540 similar, resulting in more stable conductive effects and alleviating uneven display images. In one embodiment, the material of the fourth auxiliary conductive structure 540 includes at least one of indium tin oxide, aluminum-doped zinc oxide, gallium-doped zinc oxide, fluorine-doped zinc oxide, indium zinc oxide, and indium gallium zinc oxide. In one embodiment, referring to the cross-sectional structural schematic diagram of the display panel shown in FIG. 13, the substrate 100 includes a base substrate 100 and a planarization layer 120, the planarization layer 120 is located on a side of the base substrate 110 close to the pixel defining layer 200; the partition structure 400 further includes: a second groove 420, the second groove 420 is located in the planarization layer 120, the second groove 420 communicates with the first groove 410, and the orthographic projection of the second groove 420 on the base substrate 110 is located within the range of the orthographic projection of the first groove 410 on the base substrate 110. Thus, the depth of the groove can be deepened, further improving the effect of partitioning the light-emitting functional layer 320, and further reducing the risk of crosstalk between adjacent light-emitting devices 300.

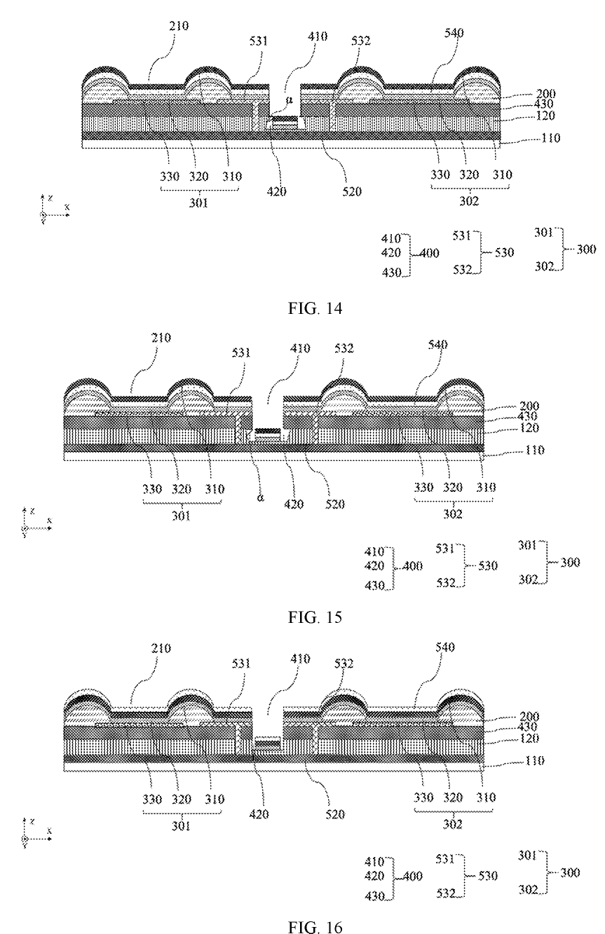

For example, referring to FIG. 13, the sidewall of the second groove 420 is perpendicular to the substrate 110. For another example, referring to FIG. 14, the width of the second groove 420 gradually decreases in a direction away from the substrate 110, and the angle α between the sidewall of the second groove 420 and the plane where the opening of the second groove 420 is located is an obtuse angle. This facilitates improving the effect of blocking the light-emitting functional layer 320, further reducing the risk of crosstalk between adjacent light-emitting devices 300. For another example, referring to FIG. 15, the width of the second groove 420 gradually increases in a direction away from the substrate 110, and the angle α between the sidewall of the second groove 420 and the plane where the opening of the second groove 420 is located is an acute angle. The second groove 420 can also enhance the effect of blocking the light-emitting functional layer 320, but the blocking effect is not as good as in the previous two cases.

In some embodiments, the depth of the second groove 420 is less than or equal to the thickness of the planarization layer 120. The second groove 420 may or may not penetrate through the planarization layer 120. In one embodiment, referring to FIGS. 13,14, or 15, the isolation structure 400 further includes: an isolation portion 430, the isolation portion 430 is located on a side of the second groove 420 close to the first groove 410, and an orthographic projection of the isolation portion 430 on the substrate 110 overlaps with an orthographic projection of the opening of the second groove 420 on the substrate 110. Thus, the isolation portion 430 and the second groove 420 form an undercut structure, which is beneficial for improving the effect of blocking the light-emitting functional layer 320. In one embodiment, the material of the isolation portion 430 includes at least one of a conductive material or an insulating material. For example, the isolation portion 430 is located between the planarization layer 120 and the second electrode layer 330, and in this case, the material of the isolation portion 430 includes an insulating material.

In a specific example, the isolation portion 430 is located between the second electrode layer 330 and the substrate 100. A through hole is provided in the isolation portion 430. An orthographic projection of the through hole on the substrate 100 is within a range of an orthographic projection of the second groove 420 on the substrate 100, and the isolation portion 430 and the second groove 420 form an undercut structure. For example, the isolation portion 430 is formed using an inorganic insulating material of at least one of silicon nitride (SiNx), silicon oxide (SiOx), and silicon oxynitride (SiON). For another example, the isolation portion 430 is disposed in the same layer as the second electrode layer 330, and the isolation portion 430 is spaced apart from the second electrode layer 330, and in this case, the material of the isolation portion 430 is the same as the material of the second electrode layer 330. In one embodiment, the isolation portion 430 extends along a circumferential direction of the second groove 420. In one embodiment, referring to FIGS. 13,14, or 15, the display panel further includes: a third auxiliary conductive structure 530, located in the first groove 410, and located on a side of the isolation portion 430 away from the substrate 110, the third auxiliary conductive structure 530 is electrically connected to the first electrode layer 310. This facilitates transmitting signals in the first electrode layer 310, reducing power consumption of the display panel.

In one embodiment, the light-emitting device 300 includes a first light-emitting device 301 and a second light-emitting device 302. The third auxiliary conductive structure 530 includes a third sub-auxiliary conductive structure 531 and a fourth sub-auxiliary conductive structure 532, the third sub-auxiliary conductive structure 531 is electrically connected to the first electrode layer 310 of the first light-emitting device 301. The fourth sub-auxiliary conductive structure 532 is electrically connected to the first electrode layer 310 of the second light-emitting device 302.

Exemplarily, in a first direction x, a width of an orthographic projection of the third auxiliary conductive structure 530 on the substrate 100 is greater than or equal to 3 μm and less than or equal to 6 μm (for example, can be 3 μm, 4 μm, 5 μm, or 6 μm, etc.). In a second direction y, a width of an orthographic projection of the third auxiliary conductive structure 530 on the substrate 100 is greater than or equal to 3 μm and less than or equal to 6 μm (for example, can be 3 μm, 4 μm, 5 μm, or 6 μm, etc.), the first direction x intersects the second direction y. For example, the third sub-auxiliary conductive structure 531 and the fourth sub-auxiliary conductive structure 532 are spaced apart; the third sub-auxiliary conductive structure 531 and the fourth sub-auxiliary conductive structure 532 are respectively electrically connected to the second auxiliary conductive structure 520 through first via holes. This facilitates achieving a full-surface cathode. Exemplarily, the second auxiliary conductive structure 520 is located on a side of the isolation portion 430 close to the substrate 100. A second via hole is provided in the isolation portion 430, and the third auxiliary conductive structure 530 is electrically connected to the second auxiliary conductive structure 520 through the second via hole. The second auxiliary conductive structure 520 may be located between the isolation portion 430 and the planarization layer 120, or may be located on a side of the planarization layer 120 close to the substrate 110.

For another example, the third sub-auxiliary conductive structure 531 and the fourth sub-auxiliary conductive structure 532 are electrically connected. For example, on a side of the pixel defining layer 200 where the first groove 410 is not provided, away from the substrate 100, the third sub-auxiliary conductive structure 531 and the fourth sub-auxiliary conductive structure 532 are electrically connected. In this case, a full-surface cathode can be achieved without providing the second auxiliary conductive structure 520. In this embodiment, providing the second auxiliary conductive structure 520 can further reduce power consumption of the display panel.

In one embodiment, the third auxiliary conductive structure 530 is disposed in the same layer as the second electrode layer 330. In one embodiment, the fourth auxiliary conductive structure 540 is located on a side of the first electrode layer 310 away from (referring to FIG. 13) and/or close to (referring to FIG. 16) the substrate 100, and the fourth auxiliary conductive structure 540 is transparent. Exemplarily, the fourth auxiliary conductive structure 540 includes a first metal element, the third auxiliary conductive structure 530 includes a fourth metal element, and the first metal element is the same as the fourth metal element. This facilitates making the conductivity of the third auxiliary conductive structure 530 and the fourth auxiliary conductive structure 540 close, resulting in a relatively stable conductive effect, which is beneficial for alleviating uneven display in the display panel.

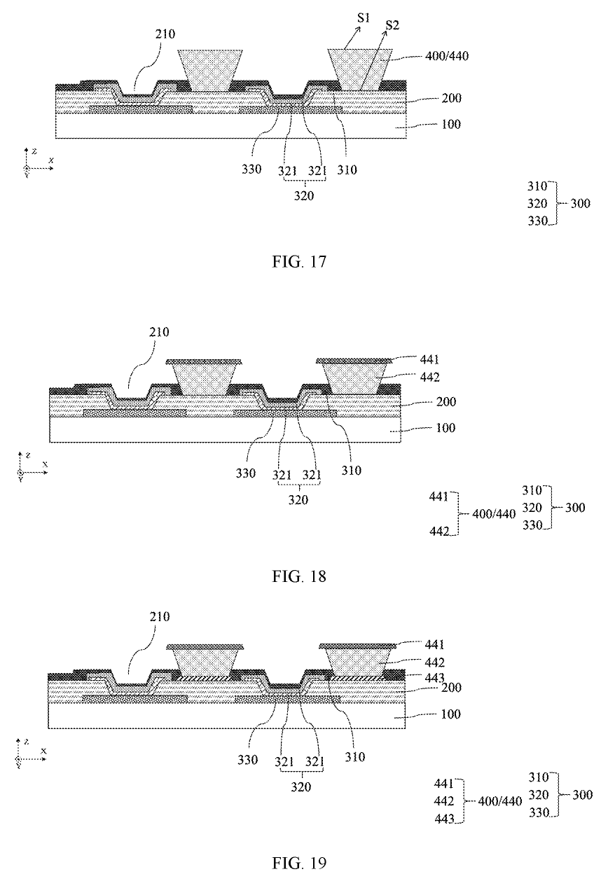

In one embodiment, referring to FIG. 17, the partition structure 400 includes an isolation structure 440, which includes a first surface S1 and a second surface S2 disposed opposite to each other, the first surface S1 being located on a side of the second surface S2 away from the pixel defining layer 200, and an orthographic projection of the second surface S2 on the substrate 100 being within an orthographic projection of the first surface S1 on the substrate 100; the isolation structure 440 is electrically connected to the first electrode layer 310. Thus, isolation of the light-emitting functional layer 320 can be achieved via the isolation structure 440, and the electrical connection between the isolation structure 440 and the first electrode layer 310 facilitates reducing the impedance of the first electrode layer 310, thereby lowering the power consumption of the display panel. In one embodiment, referring to FIG. 18, the isolation structure 440 includes a first isolation portion 441 and a second isolation portion 442, the first isolation portion 441 being located on a side of the second isolation portion 442 away from the pixel defining layer 200, and an orthographic projection of the second isolation portion 442 on the substrate 100 being within an orthographic projection of the first isolation portion 441 on the substrate 100; the second isolation portion 442 is electrically connected to the first electrode layer 310. In one embodiment, referring to FIG. 19, the isolation structure 440 further includes a third isolation portion 443 located on a side of the second isolation portion 442 close to the pixel defining layer 200, and an orthographic projection of the second isolation portion 442 on the substrate 100 being within an orthographic projection of the third isolation portion 443 on the substrate 100; the third isolation portion 443 is electrically connected to the first electrode layer 310.

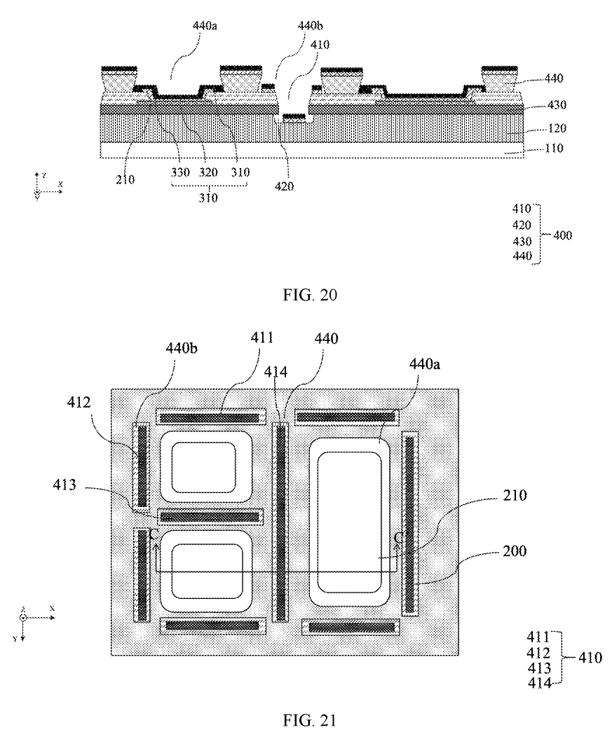

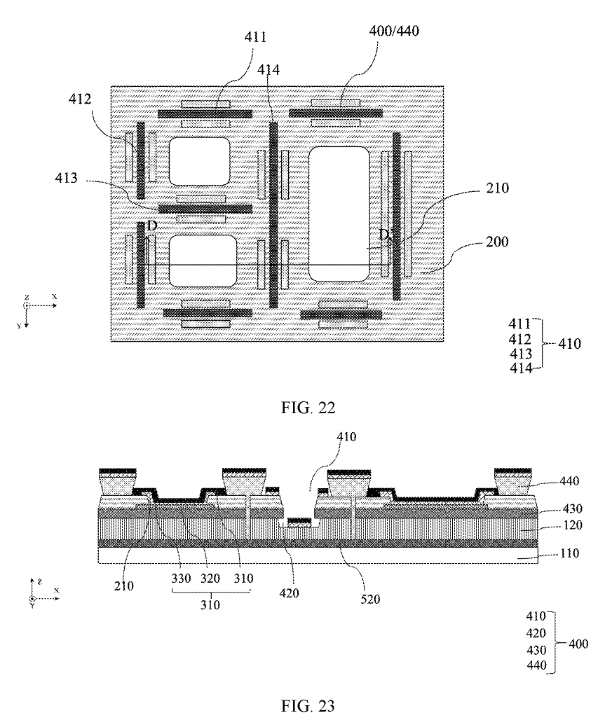

In one embodiment, referring to FIG. 20, the partition structure 400 further includes a first groove 410 located in the pixel defining layer 200. The first groove 410 surrounding at least a portion of the pixel opening 210. The isolation structure 440 surrounds at least a portion of the first groove 410. In this embodiment, the isolation structure 440 may surround a portion of the first groove 410 (referring to FIG. 21), or may completely surround the first groove 410 (referring to FIG. 22). For example, when the isolation structure 440 surrounds a portion of the first groove 410, there may be multiple isolation structures 440. For example, when the isolation structure 440 surrounds a portion of the first groove 410, at least one isolation structure 440 is disposed between adjacent light-emitting devices 300. FIG. 20 may be a cross-sectional structural schematic view of the display panel in FIG. 21 along the CC' direction. FIG. 23 may be a cross-sectional view of the display panel in FIG. 22 along the DD' direction. In one embodiment, at least one first groove 410 is disposed around a pixel opening 210. For example, multiple first grooves 410 are disposed around a pixel opening 210, and the multiple first grooves 410 are discontinuous. Referring to FIG. 21, the multiple first grooves 410 include a first sub-groove 411 and a second sub-groove 412. The first sub-groove 411 extending along a first direction X, and the second sub-groove 412 extending along a second direction Y. In the first direction X, opposite ends of the first sub-groove 411 extend beyond the pixel opening 210, and in the second direction Y, opposite ends of the second sub-groove 412 extend beyond the pixel opening 210. For example, the first direction X is perpendicular to the second direction Y. 'opposite ends of the first sub-groove 411 extend beyond the pixel opening 210' means the following. In the first direction X, the first sub-groove 411 has a first end and a second end opposite to each other. The pixel opening 210 has a third end and a fourth end opposite to each other. The first end and the third end are disposed adjacent to each other. The second end and the fourth end are disposed adjacent to each other. The first end is located on a side of the third end away from the fourth end. The second end is located on a side of the fourth end away from the third end. The meaning of "opposite ends of the second sub-groove 412 extend beyond the pixel opening 210" can be understood with reference to the above explanation, and will not be elaborated further. For example, in the first direction X, one first groove 410 is disposed on each of opposite sides of the pixel opening 210, and in the second direction Y, one first groove 410 is disposed on each of opposite sides of the pixel opening 210, which can effectively isolate the light-emitting functional layer 320, facilitating reduction of the probability of crosstalk between adjacent light-emitting devices 300.

In one embodiment, referring to FIG. 21, the first groove 410 further includes a third sub-groove 413 and a fourth sub-groove 414. In the second direction Y, the first sub-groove 411 and the third sub-groove 413 are located on opposite sides of the pixel opening 210. In the first direction X, the second sub-groove 412 and the fourth sub-groove 414 are located on opposite sides of the pixel opening 210. In the first direction X, opposite ends of the third sub-groove 413 extend beyond the pixel opening 210. In the second direction Y, opposite ends of the fourth sub-groove 414 extend beyond the pixel opening 210. The meanings of "opposite ends of the third sub-groove 413 extend beyond the pixel opening 210" and "opposite ends of the fourth sub-groove 414 extend beyond the pixel opening 210" can be understood with reference to the above explanation, and will not be elaborated further.

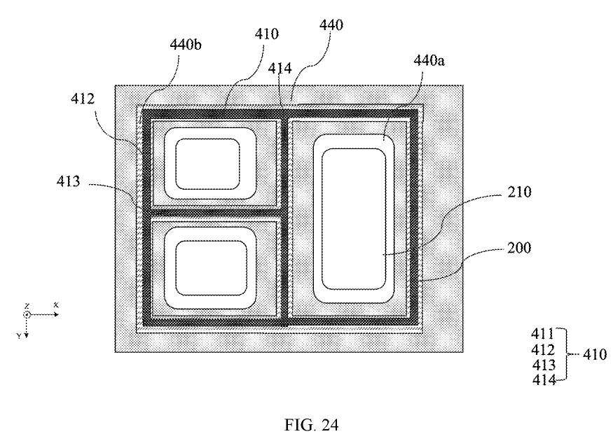

For example, the number of first grooves 410 around a pixel opening 210 is two. The two first grooves 410 are disposed opposite to each other in the first direction X, each first groove 410 has a "C"-shaped orthographic projection on the substrate 100, and the length of the pixel opening 210 surrounded by each first groove 410 accounts for 30% to 50% of the perimeter of the pixel opening 210, with the two first grooves being spaced apart. In one embodiment, the first sub-groove 411, the second sub-groove 412, the third sub-groove 413, and the fourth sub-groove 414 are sequentially connected end to end. Thus, the first sub-groove 411, the second sub-groove 412, the third sub-groove 413, and the fourth sub-groove 414 form a closed structure (referring to FIG. 24), constituting an annular through groove. This further improves the effect of the partition structure 400 in isolating the light-emitting functional layer 320 between adjacent light-emitting devices 300, and is more conducive to reducing the probability of crosstalk between adjacent light-emitting devices 300.

For example, as shown in FIG. 24, one first groove 410 surrounds the periphery of the pixel opening 210, thereby achieving a better effect of isolating the light-emitting functional layer 320, which is conducive to reducing the probability of crosstalk between adjacent light-emitting devices 300.

In one embodiment, there is at least one first groove 410 between adjacent pixel openings 210. Thus, the effect of cutting off the light-emitting functional layer 320 is better, which is conducive to reducing the probability of crosstalk between adjacent light-emitting devices 300. In one embodiment, the depth of the first groove 410 is less than or equal to the thickness of the pixel defining layer 200. The first groove 410 may penetrate through the pixel defining layer 200 or may not penetrate through the pixel defining layer 200. In one embodiment, the depth of the first groove 410 is greater than or equal to 1 μm and less than or equal to 2 μm, for example, it may be 1 μm, 1.2 μm, 1.4 μm, 1.6 μm, 1.8 μm, 2 μm, etc. In one embodiment, the width of the first groove 410 is greater than or equal to 1 μm and less than or equal to 10 μm, for example, it may be 1 μm, 2 μm, 4 μm, 6 μm, 8 μm, 10 μm, etc.

In one embodiment, referring to FIGS. 22 and 23 , along the extension direction of the first groove 410, the length of the isolation structure 440 is less than the length of the first groove 410; that is, the isolation structure 440 may surround a portion of the first groove 410, in which case the isolation structure 440 includes a plurality of structures arranged at intervals

The display panel further includes a second auxiliary conductive structure 520, the second auxiliary conductive structure 520 is located on a side of the second electrode layer 330 away from the pixel defining layer 200, and the isolation structure 440 is electrically connected to the second auxiliary conductive structure 520. For example, the second auxiliary conductive structure 520 is located on a side of the planarization layer 120 away from the second electrode layer 330, and the isolation structure 440 is electrically connected to the second auxiliary conductive structure 520 through a first via hole. Thus, it is conducive to realizing a full-surface cathode. For example, there is at least one isolation structure 440 between adjacent light-emitting devices 300.

For example, there is at least one first groove 410 between adjacent light-emitting devices 300, and there is at least one isolation structure between the first groove 410 and the light-emitting device 300.

In one embodiment, referring to FIG. 21, the isolation structure 440 defines a plurality of isolation openings 440a, and the orthographic projection of the pixel opening 210 on the substrate 100 is within the range of the orthographic projection of the isolation opening 440a on the substrate 100; patents CN118251982A, CN115666161A, CN116648095A, CN117062489A, CN118678742A, CN118785761A, CN115224220A, CN118678729A, CN118660529A, and CN118660589 describe relevant content of the isolation structure 440 for reference. In one embodiment, the isolation structure 440 has a first opening 440b, and the orthographic projection of the first groove 410 on the substrate 100 is within the range of the orthographic projection of the first opening 440b on the substrate 100; the shape of the orthographic projection of the isolation structure 440 on the substrate 100 includes a mesh shape. Thus, the first electrode layers 310 of adjacent light-emitting devices 300 are connected together through the isolation structure 440, realizing a full-surface cathode.

Exemplarily, referring to FIG. 22, the first groove 410 may surround a portion of the pixel opening 210. Exemplarily, referring to FIG. 24, the first groove 410 may completely surround the pixel opening 210, in which case the first groove 410 divides the isolation structure 440 into a plurality of isolation structures 440 arranged at intervals, and the effect of cutting off the light-emitting functional layer 320 is more excellent.

In one embodiment, referring to FIGS. 20 and 23 , the blocking structure 400 further includes: a second groove 420, the second groove 420 is located in the planarization layer 120, the second groove 420 communicates with the first groove 410, and the orthographic projection of the first groove 410 on the substrate 110 is within the range of the orthographic projection of the second groove 420 on the substrate 110. Exemplarily, along a direction away from the substrate 110, the width of the second groove 420 gradually decreases; or, the sidewall of the second groove 420 is perpendicular to the substrate 110. Thus, the effect of cutting off the light-emitting functional layer 320 can be further improved, further reducing crosstalk between adjacent light-emitting devices 300. In one embodiment, the blocking structure further includes: a blocking portion 430, the blocking portion 430 is located on a side of the second groove 420 close to the first groove 410, and the orthographic projection of the blocking portion 430 on the substrate 110 overlaps with the orthographic projection of the opening of the second groove 420 on the substrate 110. Thus, the blocking portion 430 and the second groove 420 form an undercut structure, which is conducive to improving the effect of cutting off the light-emitting functional layer 320. In a specific example, the blocking portion 430 is located between the second electrode layer 330 and the substrate 110, the material of the blocking portion 430 includes an insulating material (for example, the blocking portion 430 is formed using an inorganic insulating material of at least one of silicon nitride (SiNx), silicon oxide (SiOx), and silicon oxynitride (SiON)), a through hole is provided in the blocking portion 430, the orthographic projection of the through hole on the substrate 100 is within the range of the orthographic projection of the second groove 420 on the substrate 110, and the blocking portion 430 and the second groove 420 form an undercut structure. Exemplarily, the second auxiliary conductive structure 520 is located between the blocking portion 430 and the planarization layer 120, the blocking portion 430 has a second via hole, and the isolation structure 440 is electrically connected to the second auxiliary conductive structure 520 through the second via hole. In one embodiment, the blocking portion 430 extends along the circumferential direction of the second groove 420.

An embodiment of the present application provides a display device, including the above display panel. In addition to including the display panel of the present application, the display device may also include structures that a conventional display device should have, such as a battery, a chip, a housing, and other structures, which will not be described in detail here. The display device may include a device with image processing capabilities, for example, a mobile phone, a desktop computer, a laptop computer, a tablet computer, a vehicle display, a wearable device, etc.

The basic principles of the present disclosure have been described above in conjunction with specific embodiments. However, the advantages, benefits, effects, etc. mentioned in the present disclosure are examples and not limitations, and these advantages, benefits, effects, etc. should not be considered as essential for each embodiment of the present disclosure. In addition, the specific details disclosed above are to illustration and ease of understanding only, and are not limitations; these details do not limit the present disclosure to being implemented by adopting the above specific details. The foregoing description is for illustration purposes only and is not intended to be exhaustive or to limit the disclosure to the precise forms disclosed.

What is claimed is:

1. A display panel, comprising:
a substrate;
a pixel defining layer located on one side of the substrate, the pixel defining layer defining a plurality of pixel openings;
a plurality of light-emitting devices, each light-emitting device comprising a light-emitting functional layer and a first electrode layer, the light-emitting functional layer and the first electrode layer being located in the pixel openings;
wherein the first electrode layer is located on a side of the light-emitting functional layer away from the substrate, and a thickness of the first electrode layer is less than or equal to 10 nm; along a direction perpendicular to a plane where the substrate is located, the light-emitting functional layer comprises at least two stacked light-emitting units, adjacent light-emitting units being connected in series.

2. The display panel according to claim 1, further comprising: a partition structure surrounding at least part of the pixel openings, configured to partition the light-emitting functional layer between adjacent light-emitting devices, wherein at least one partition structure is provided between adjacent pixel openings.

3. The display panel according to claim 2, wherein a number of partition structures on a periphery of one pixel opening is at least one, the at least one partition structure comprising a first sub-partition structure and a second sub-partition structure, the first sub-partition structure extending along a first direction, the second sub-partition structure extending along a second direction; in the first direction, opposite ends of the first sub-partition structure extend beyond the pixel opening; in the second direction, opposite ends of the second sub-partition structure extend beyond the pixel opening; the first direction intersecting the second direction.

4. The display panel according to claim 3, wherein the partition structure further comprises a third sub-partition structure and a fourth sub-partition structure; in the second direction, the first sub-partition structure and the third sub-partition structure are located on opposite sides of the pixel opening; in the first direction, the second sub-partition structure and the fourth sub-partition structure are located on opposite sides of the pixel opening; in the first direction, opposite ends of the third sub-partition structure extend beyond the pixel opening; in the second direction, opposite ends of the fourth sub-partition structure extend beyond the pixel opening.

5. The display panel according to claim 2, wherein the partition structure comprises a first groove, the first groove being located in the pixel defining layer, the first groove surrounding at least part of the pixel openings, a depth of the first groove being less than or equal to a thickness of the pixel defining layer.

6. The display panel according to claim 5, wherein a number of first grooves on a periphery of one pixel opening is at least one, the first groove comprising a first sub-groove and a second sub-groove, the first sub-groove extending along a first direction, the second sub-groove extending along a second direction; in the first direction, opposite ends of the first sub-groove extend beyond the pixel opening, in the second direction, opposite ends of the second sub-groove extend beyond the pixel opening;
the first groove further comprises a third sub-groove and a fourth sub-groove, in the second direction, the first sub-groove and the third sub-groove are located on opposite sides of the pixel opening, in the first direction, the second sub-groove and the fourth sub-groove are located on opposite sides of the pixel opening; in the first direction, opposite ends of the third sub-groove extend beyond the pixel opening; in the second direction, opposite ends of the fourth sub-groove extend beyond the pixel opening;
at least one first groove is provided between adjacent pixel openings.

7. The display panel according to claim 5, wherein the display panel further comprises: a first auxiliary conductive structure located between the pixel defining layer and the substrate, at least part of the first auxiliary conductive structure being exposed in the first groove, the first auxiliary conductive structure being electrically connected to the first electrode layer;
the light-emitting devices comprise a first light-emitting device and a second light-emitting device, the first auxiliary conductive structure comprising a first sub-auxiliary conductive structure and a second sub-auxiliary conductive structure, the first sub-auxiliary conductive structure being electrically connected to the first electrode layer of the first light-emitting device, the second sub-auxiliary conductive structure being electrically connected to the first electrode layer of the second light-emitting device;
the first sub-auxiliary conductive structure and the second sub-auxiliary conductive structure are spaced apart, or the first sub-auxiliary conductive structure and the second sub-auxiliary conductive structure are electrically connected;
the first groove penetrates the pixel defining layer, at least part of the first sub-auxiliary conductive structure and at least part of the second sub-auxiliary conductive structure being located in the first groove.

8. The display panel according to claim 7, wherein the light-emitting device further comprises a second electrode layer located between the pixel defining layer and the substrate, at least part of the second electrode layer being exposed in the pixel opening, the first auxiliary conductive structure and the second electrode layer being disposed in a same layer;
the display panel further comprises a second auxiliary conductive structure located on a side of the second electrode layer away from the pixel defining layer, the first auxiliary conductive structure being electrically connected to the second auxiliary conductive structure.

9. The display panel according to claim 8, wherein the substrate comprises a planarization layer, the planarization layer having a first via hole; the second auxiliary conductive structure is located on a side of the planarization layer away from the second electrode layer, and the first auxiliary conductive structure is electrically connected to the second auxiliary conductive structure through the first via hole; the display panel further comprises: a fourth auxiliary conductive structure, located on a side of the first electrode layer away from and/or close to the substrate, the fourth auxiliary conductive structure being transparent.

10. The display panel according to claim 5, wherein the substrate comprises a base substrate and a planarization layer, the planarization layer being located on a side of the base substrate close to the pixel defining layer; the partition structure further comprises: a second groove, the second groove being located in the planarization layer, the second groove being in communication with the first groove, and an orthographic projection of the second groove on the base substrate being within a range of an orthographic projection of the first groove on the base substrate.

11. The display panel according to claim 10, wherein, in a direction away from the base substrate, a width of the second groove gradually decreases; or, a sidewall of the second groove is perpendicular to the base substrate.

12. The display panel according to claim 10, wherein the partition structure further comprises: a partition portion, located on a side of the second groove close to the first groove, an orthographic projection of the partition portion on the base substrate overlapping with an orthographic projection of an opening of the second groove on the base substrate;
the light-emitting device further comprises a second electrode layer, located between the pixel defining layer and the substrate, the second electrode layer being at least partially exposed in the pixel opening; the partition portion is located between the planarization layer and the second electrode layer, or, the partition portion is arranged in a same layer as the second electrode layer and is spaced apart from the second electrode layer; the partition portion extends along a periphery of the second groove.

13. The display panel according to claim 10, wherein the display panel further comprises: a third auxiliary conductive structure, located in the first groove and on a side of the partition portion away from the base substrate, the third auxiliary conductive structure being electrically connected to the first electrode layer;
the light-emitting device comprises a first light-emitting device and a second light-emitting device, the third auxiliary conductive structure comprises a third sub-auxiliary conductive structure and a fourth sub-auxiliary conductive structure, the third sub-auxiliary conductive structure being electrically connected to the first electrode layer of the first light-emitting device, and the fourth sub-auxiliary conductive structure being electrically connected to the first electrode layer of the second light-emitting device; the third sub-auxiliary conductive structure and the fourth sub-auxiliary conductive structure are spaced apart, or, the third sub-auxiliary conductive structure and the fourth sub-auxiliary conductive structure are electrically connected; the third auxiliary conductive structure is arranged in the same layer as the second electrode layer.

14. The display panel according to claim 13, wherein, in a first direction, a width of an orthographic projection of the third auxiliary conductive structure on the substrate is greater than or equal to 3 μm and less than or equal to 6 μm; in a second direction, a width of an orthographic projection of the third auxiliary conductive structure on the substrate is greater than or equal to 3 μm and less than or equal to 6 μm, the first direction intersecting the second direction.

15. The display panel according to claim 2, wherein the partition structure comprises an isolation structure, the isolation structure comprising a first surface and a second surface disposed opposite to each other, the first surface being located on a side of the second surface away from the pixel defining layer, an orthographic projection of the second surface on the substrate being within a range of an orthographic projection of the first surface on the substrate; the isolation structure is electrically connected to the first electrode layer;
the isolation structure comprises a first isolation portion and a second isolation portion, the first isolation portion being located on a side of the second isolation portion away from the pixel defining layer, an orthographic projection of the second isolation portion on the substrate being within a range of an orthographic projection of the first isolation portion on the substrate; the second isolation portion is electrically connected to the first electrode layer;
the isolation structure further comprises a third isolation portion, located on a side of the second isolation portion close to the pixel defining layer, an orthographic projection of the second isolation portion on the substrate being within a range of an orthographic projection of the third isolation portion on the substrate; the third isolation portion is electrically connected to the first electrode layer.

16. The display panel according to claim 15, wherein the isolation structure encloses a plurality of isolation openings, an orthographic projection of the pixel opening on the substrate being within a range of an orthographic projection of the isolation opening on the substrate; the isolation structure defines a first opening, and an orthographic projection of the first groove on the substrate being within a range of an orthographic projection of the first opening on the substrate; a shape of an orthographic projection of the isolation structure on the substrate comprises a mesh shape.

17. The display panel according to claim 15, wherein the light-emitting device further comprises a second electrode layer, located between the pixel defining layer and the substrate, the second electrode layer being at least partially exposed in the pixel opening; along an extension direction of the first groove, a length of the isolation structure is less than a length of the first groove;
the display panel further comprises a second auxiliary conductive structure, located on a side of the second electrode layer away from the pixel defining layer, the isolation structure being electrically connected to the second auxiliary conductive structure;
the substrate comprises a planarization layer, the planarization layer having a first via hole; the second auxiliary conductive structure is located on a side of the planarization layer away from the second electrode layer, and the isolation structure is electrically connected to the second auxiliary conductive structure through the first via hole.

18. The display panel according to claim 15, wherein the substrate comprises a base substrate and a planarization layer, the planarization layer being located on a side of the base substrate adjacent to the pixel defining layer;
the partition structure further comprises: a second groove, the second groove being located in the planarization layer, the second groove being in communication with the first groove, and an orthographic projection of the first groove on the base substrate being within a range of an orthographic projection of the second groove on the base substrate;
the partition structure further comprises: a partition portion, the partition portion being located on a side of the second groove adjacent to the first groove, and an orthographic projection of the partition portion on the base substrate overlapping with an orthographic projection of an opening of the second groove on the base substrate;
the light-emitting device further comprises a second electrode layer, located between the pixel defining layer and the substrate, the second electrode layer being at least partially exposed in the pixel opening; the partition portion being located between the planarization layer and the second electrode layer; the partition portion extending along a circumferential direction of the second groove;
the display panel further comprises a second auxiliary conductive structure, located on a side of the partition portion away from the pixel defining layer, the partition portion having a second via hole therein, and the isolation structure being electrically connected to the second auxiliary conductive structure through the second via hole.

19. The display panel according to claim 1, wherein a thickness of the first electrode layer is less than or equal to 5 nm; the display panel further comprises: a fourth auxiliary conductive structure, located on a side of the first electrode layer away from or adjacent to the substrate, the fourth auxiliary conductive structure being transparent; a material of the fourth auxiliary conductive structure comprises at least one of indium tin oxide, aluminum-doped zinc oxide, gallium-doped zinc oxide, fluorine-doped zinc oxide, indium zinc oxide, and indium gallium zinc oxide.

20. A display device, comprising the display panel according to the claim 1.
